(19) United States
(12) Patent Application Publication
(10) Pub. No.: US 2026/0274649 A1
(43) Pub. Date: Sep. 17, 2026

(54) MICRO-ELECTRO-MECHANICAL SYSTEM PACKAGE

(71) Applicant: Vanguard International Semiconductor Corporation, Hsinchu (TW)

(72) Inventors: RANGANATHAN NAGARAJAN, Singapore (SG); Ramachandramurthy Pradeep Yelehanka, Singapore (SG); Guofu Zhou, Singapore (SG); Rohit Pulikkal Kizhakkeyil, Singapore (SG)

(73) Assignee: Vanguard International Semiconductor Corporation, Hsinchu (TW)

(21) Appl. No.: 19/079,501

(22) Filed: Mar. 14, 2025

(51) Int. Cl. B81B 7/00; H10W 72/30

(52) U.S. Cl. CPC B81B 7/0006; B81B 2207/03; H10W 72/344; H10W 72/387

(57) ABSTRACT

A MEMS package includes a first substrate, an interconnect layer, a MEMS device layer, a stand-off structure, a bonding material layer and a second substrate. The interconnect layer is disposed on the first substrate. The MEMS device layer includes a MEMS device and is disposed above the interconnect layer. The stand-off structure is disposed under the MEMS device layer, around the MEMS device and bonded to the interconnect layer. The stand-off structure includes an inner sidewall, an outer sidewall and a bottom surface. The bonding material layer is applied on the outer sidewall and a portion of the bottom surface of the stand-off structure. In addition, the second substrate includes a cavity and is bonded to the MEMS device layer.

### BACKGROUND OF THE INVENTION

### FIELD OF THE INVENTION

The present disclosure relates generally to micro-electro-mechanical system (MEMS) technology, and more particularly to MEMS packages that include a bonding structure to limit bond misalignment and bonding material overflow.

### DESCRIPTION OF THE PRIOR ART

Micro-electro-mechanical system (MEMS) devices are microscopic devices that integrate mechanical and electrical components to sense physical quantities and/or to interact with the surrounding environment. MEMS devices, for example, accelerometers, gyroscopes, pressure sensors and microphones, have become widespread in many electronic products, such as tablet computers, automobiles, and smartphones. A MEMS wafer is usually aligned and bonded to another support wafer by eutectic bonding. During the eutectic bonding, the molten bonding material causes misalignment between the bonded wafers. Also, the molten bonding material is squeezed out in all directions. Therefore, conventional MEMS packages still have some issues stemming from eutectic bonding that need to be overcome.

### SUMMARY OF THE INVENTION

In view of this, the present disclosure provides micro-electro-mechanical system (MEMS) packages that include a bonding material layer and a dielectric stopper to control and/or limit bond misalignment and bonding material overflow. The bonding material layer is recessed inwardly from the inner sidewall of a stand-off structure to serve as a bonding structure. Furthermore, the dielectric stopper is disposed around the bonding material layer and the stand-off structure.

According to an embodiment of the present disclosure, a MEMS package is provided and includes a first substrate, an interconnect layer, a MEMS device layer, a stand-off structure, a bonding material layer and a second substrate. The interconnect layer is disposed on the first substrate. The MEMS device layer includes a MEMS device and is disposed above the interconnect layer. The stand-off structure is disposed under the MEMS device layer, around the MEMS device and bonded to the interconnect layer. The stand-off structure includes an inner sidewall, an outer sidewall and a bottom surface. The bonding material layer is applied on the outer sidewall and a portion of the bottom surface of the stand-off structure. In addition, the second substrate includes a cavity and is bonded to the MEMS device layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a MEMS package according to one embodiment of the present disclosure.

FIG. 2 is an enlarged cross-sectional view of a partial area A in the MEMS package of FIG. 1 according to one embodiment of the present disclosure.

FIGS. 3 ,4, 5, 6, 7, 8 and 9 are schematic cross-sectional views of some stages of a method of fabricating a MEMS package according to one embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the structure in use or operation in addition to the orientation depicted in the figures. For example, if the structure in the figures is turned over, elements described as "below" and/or "under" other elements or features would then be oriented "above" and/or "over" the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as "first", "second", and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms "coupled to" and "electrically connected to" include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS packages including a bonding material layer and a dielectric stopper to control and/or limit bond misalignment and molten bonding material overflow within the bonded device area. The bonding material layer is recessed from the inner sidewall of a stand-off structure, thereby preventing lateral overflow of molten bonding material. The dielectric stopper is disposed around the bonding material layer and the stand-off structure. The dielectric stopper is sufficiently thick to physically stop wafer skidding during bonding, thereby limiting bond misalignment. Furthermore, the dielectric stopper has an opening that is sufficiently wide to accommodate the bond alignment tolerance of the bonder tool. Therefore, the yield and quality of the MEMS packages are enhanced.

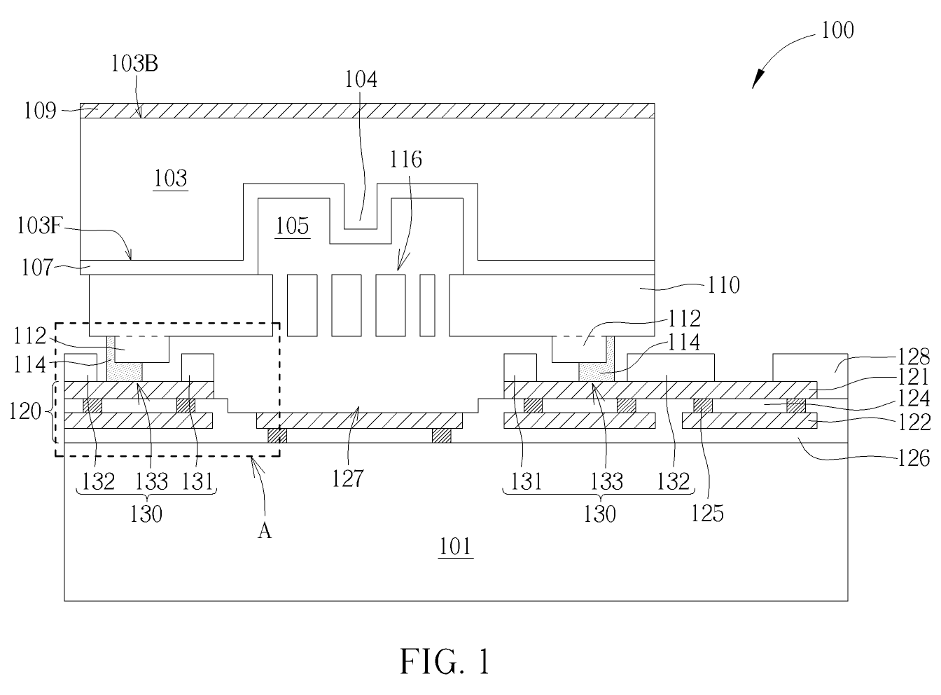

FIG. 1 is a schematic cross-sectional view of a MEMS package 100 according to one embodiment of the present disclosure. The MEMS package 100 includes a first substrate 101, an interconnect layer 120, a MEMS device layer 110, a stand-off structure 112, a bonding material layer 114, and a second substrate 103. The first substrate 101 may be a silicon wafer and includes multiple CMOS transistors or other elements formed therein. The interconnect layer 120 is disposed on the first substrate 101. The interconnect layer 120 includes multiple metal layers such as a top metal layer 121 and a second-to-last metal layer 122, multiple inter-metal dielectric (IMD) layers 124 and 126, and multiple vias 125 in the IMD layers. Some vias 125 connect the top metal layer 121 to the second-to-last metal layer 122. Other vias 125 connect the second-to-last metal layer 122 to the CMOS transistors or other elements in the first substrate 101. The interconnect layer 120 is thereby electrically coupled to the CMOS transistors or other elements in the first substrate 101. The interconnect layer 120 and the first substrate 101 together may be referred to as a CMOS/interconnect wafer. Furthermore, a dielectric stopper 130 and a passivation layer 128 are disposed on the interconnect layer 120. A bond pad of the top metal layer 121 is exposed by the passivation layer 128. The bond pad is configured to be connected to a ground voltage. A seal ring of the top metal layer 121 is exposed by the dielectric stopper 130.

The MEMS device layer 110 includes a MEMS device 116 and is disposed above the interconnect layer 120. The MEMS device layer 110 includes features such as trenches, cantilever beams, membranes, and proof masses to construct the MEMS device 116, for example, an accelerometer, a gyroscope, an inertial measurement unit (IMU) device, and/or other MEMS device. The stand-off structure 112 is disposed under the MEMS device layer 110 and around the MEMS device 116. The stand-off structure 112 is a bond ring protruding towards the interconnect layer 120. The stand-off structure 112 is integrated with the MEMS device layer 110 and has the same composition as the MEMS device layer. In some embodiments, the composition of the MEMS device layer 120 and the stand-off structure 112 may be doped silicon or doped polysilicon. The MEMS device layer 110 is bonded to the interconnect layer 110 through the stand-off structure 112 and the bonding material layer 114 to provide a hermetic seal for the MEMS device 116. The bonding material layer 114 is recessed from the side of the stand-off structure 112 facing the MEMS device 116.

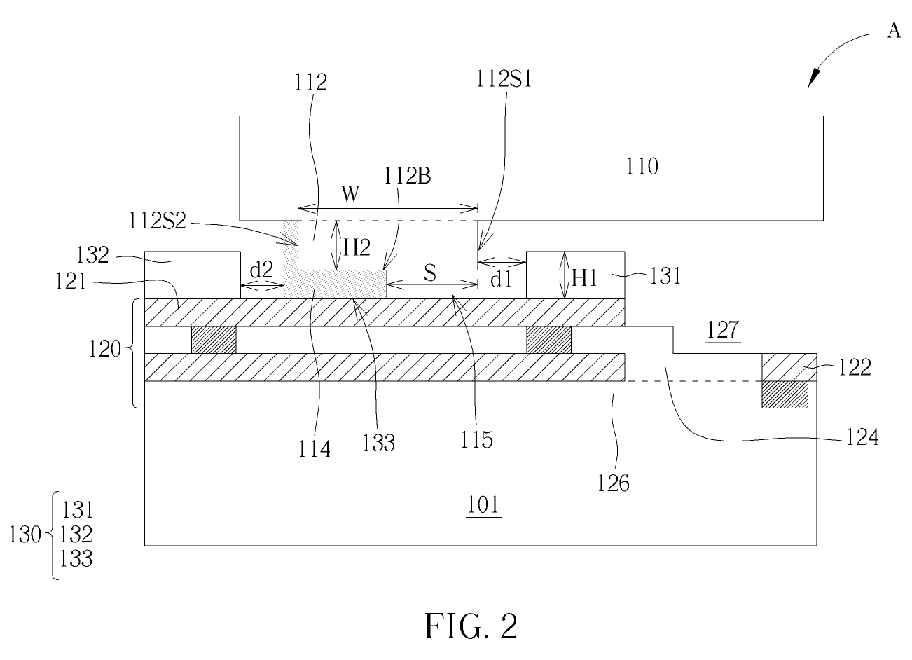

FIG. 2 is an enlarged cross-sectional view of a partial area A in the MEMS package 100 of FIG. 1 according to one embodiment of the present disclosure. Referring to FIG. 2, the stand-off structure 112 includes an inner sidewall 112S1, an outer sidewall 112S2 and a bottom surface 112B. The bonding material layer 114 is applied on the outer sidewall 112S2 and a portion of the bottom surface 112B of the stand-off structure 112, but not applied on the inner sidewall 112S1. Therefore, the bonding material layer 114 on the bottom surface 112B is indented a recessed distance S from the inner sidewall 112S1. In some embodiments, the recessed distance S may be less than 10% of a width W of the stand-off structure 112. For example, the recessed distance S may be less than about 5 µm. The bonding material layer 114 has a lateral recess 115 directly below the stand-off structure 112 and near the inner sidewall 112S1 of the stand-off structure. Referring to FIGS. 1 and 2, the lateral recess 115 of the bonding material layer 114 faces the MEMS device 116.

The bonding material layer 114 may include a eutectic bonding material or a thermo-compression bonding material. In some embodiments, the eutectic bonding material may include a eutectic alloy of aluminum (Al) and germanium (Ge), i.e., Al-Ge. The eutectic bonding material may include other eutectic alloys, such as Au-Ge, Cu-Sn, Au-Sn, Au-Si, or Al-Si, but is not limited thereto. In some embodiments, the thermo-compression bonding material may include Cu, Au, Al, Ge, or Sn, but is not limited thereto.

The dielectric stopper 130 includes a first portion 131, a second portion 132 and an opening 133. In some embodiments, the composition of the dielectric stopper 130 includes silicon oxide, silicon nitride or a combination thereof. Moreover, the dielectric stopper 130 and the passivation layer 128 may have the same composition. As shown in FIG. 1, the stand-off structure 112 is a bond ring, the first portion 131 is inside the stand-off structure 112, and the second portion 132 is outside the stand-off structure 112. The seal ring of the top metal layer 121 is exposed through the opening 133. The stand-off structure 112 and the bonding material layer 114 are disposed in the opening 133 of the dielectric stopper 130, and bonded to the seal ring of the interconnect layer 120.

In addition, referring to FIG. 2, the inner sidewall 112S1 of the stand-off structure 112 is spaced from the first portion 131 of the dielectric stopper 130 by a first distance d1. In some embodiments, the first distance d1 may be at least about 5 µm. Moreover, the first distance d1 is greater than 5 µm. The bonding material layer 114 on the outer sidewall 112S2 of the stand-off structure 112 is also spaced from the second portion 132 of the dielectric stopper 130 by a second distance d2. In some embodiments, the second distance d2 may be at least about 5 µm. Moreover, the second distance d2 is greater than 5 µm. The first distance d1 may be the same as or slightly greater than the second distance d2.

Furthermore, referring to FIG. 2, the top surface of the dielectric stopper 130 is higher than the bottom surface 112B of the stand-off structure 112. The dielectric stopper 130 has a first thickness H1. The stand-off structure 112 has a second thickness H2. The first thickness H1 may be greater than the thickness of the bonding material layer 114 on the stand-off structure 112, and less than half of the second thickness H2. In addition, the bottom surface of the opening 133, the bottom surface of the dielectric stopper 130, and the bottom surface of the bonding material layer 114 are all on the same plane.

As shown in FIGS. 1 and 2, the dielectric stopper 130 and the bonding material layer 114 are in direct contact with and disposed on the seal ring of the top metal layer 121. The IMD layer 124 is disposed between the top metal layer 121 and the second-to-last metal layer 122. In addition, the interconnect layer 120 includes a stepped recess 127 directly beneath the MEMS device 116. The stepped recess 127 is disposed in both the top metal layer 121 and the IMD layer 124 and. A portion of the second-to-last metal layer 122 is exposed from the stepped recess 127 and directly beneath the MEMS device 116. The first portion 131 of the dielectric stopper 130 is adjacent to and surrounds the stepped recess 127.

Moreover, referring to FIG. 1, the second substrate 103 is bonded to the MEMS device layer 110 through a bonding layer 107, for example, a silicon oxide layer. The second substrate 103 may be a silicon wafer, and has a front surface 103F opposite to a back surface 103B. The second substrate 103 may be referred to as a cap wafer. A cavity 105 is formed in the second substrate 103 and near the front surface 103F. The cavity 105 is located directly above the MEMS device 116. A stop bump 104 is formed in the cavity 105 and protrudes towards the MEMS device 116. The stop bump 104 is integrated into and has the same composition as the second substrate 103. The stop bump 104 may correspond to a proof mass of the MEMS device 116, and may have a gap to the MEMS device 116. The stop bump 104 limits the movement range of the MEMS device 116, thereby preventing the MEMS device 116 from breakage. The bonding layer 107 is disposed between the MEMS device layer 110 and the second substrate 103, and may be further conformally extended into the cavity 105 and on the stop bump 104. In addition, there is a metal layer 109 on the back surface 103B of the second substrate 103. The metal layer 109 is provided for radio frequency (RF) shielding and/or grounding. The metal layer 109 may be electrically connected to the bond pad of the top metal layer in the interconnect layer 120 for grounding.

According to embodiments of the present disclosure, the MEMS package 100 includes the bonding material layer 114 indented the recessed distance S from the inner sidewall 112S1 of the stand-off structure 112. This prevents molten bonding material overflow when the MEMS device layer 110 is bonded to the interconnect layer 120. Furthermore, the bonding material layer 114 is recessed to prevent molten bonding material from squeezing out under high-pressure bonding. The control and/or limitation of molten bonding material overflow further prevents electrical interconnect shorting and/or metallic contamination of adjacent structures on the interconnect layer 120.

Furthermore, the MEMS package 100 includes the dielectric stopper 130, disposed on the interconnect layer 120 around the stand-off structure 112 and the bonding material layer 114. The dielectric stopper 130 is sufficiently thick to physically prevent the stand-off structure 112 from skidding during bonding of the MEMS device layer 110 to the interconnect layer 120, thereby limiting bonded misalignment. In addition, the dielectric stopper 130 has the opening 133 that is sufficiently wide to accommodate the stand-off structure 112 and the bonding material layer 114, thereby increasing the bond alignment tolerance of the bonder tool. The opening 133 of the dielectric stopper 130 is also helpful for self-alignment of the stand-off structure 112 with the seal ring of the interconnect layer 120. The width of the opening 133 of the dielectric stopper 130 may be adjusted based on the bonder tool’s capability.

In the MEMS package 100, the bonding material layer 114 and dielectric stopper 130 are particularly useful for high-pressure and/or high-temperature bonding. For example, the bond force for bonding the MEMS device layer 110 to the interconnect layer 120 may be in the range of 20 kN to 60 kN. The thickness of the dielectric stopper 130 is adjusted as desired by the bonding pressure and/or bonding temperature. Furthermore, the architecture of the bonding material layer recessed from the inner sidewall of the stand-off structure, within the opening of the dielectric stopper, and over the seal ring of the interconnect layer is also suitable for three-dimensional integrated circuit (3D-IC) fabrication to limit bond misalignment and bonding material overflow.

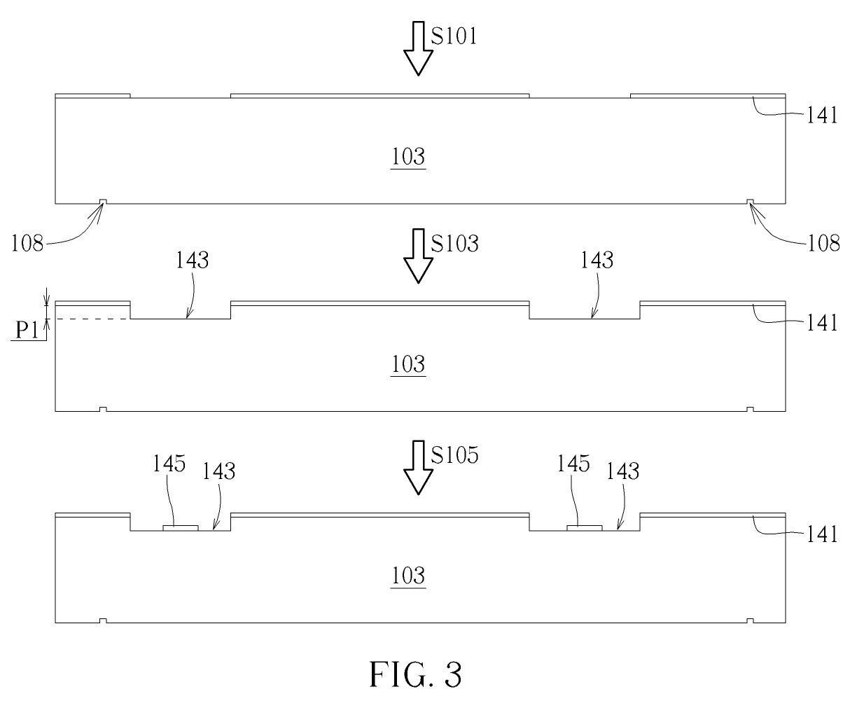

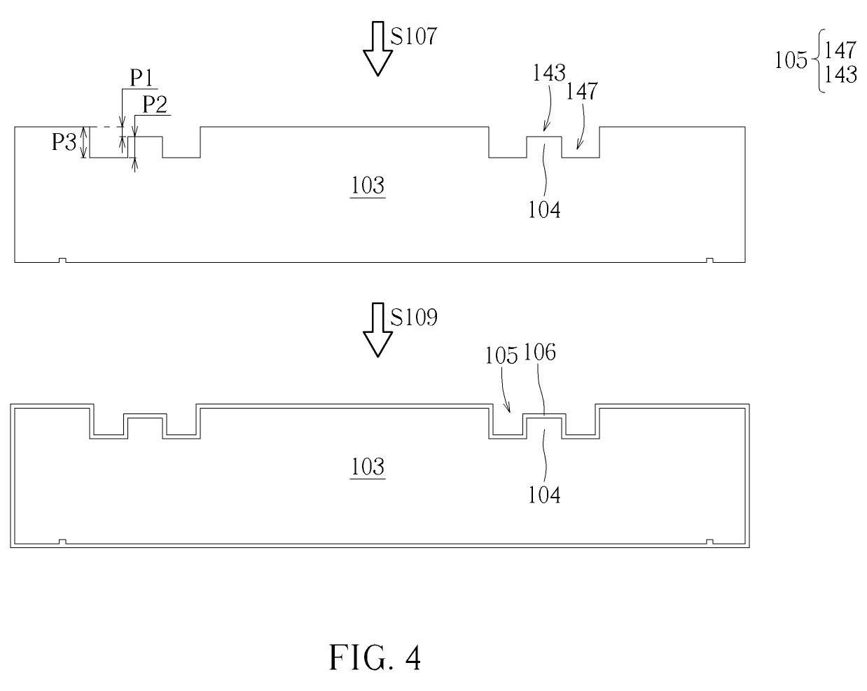

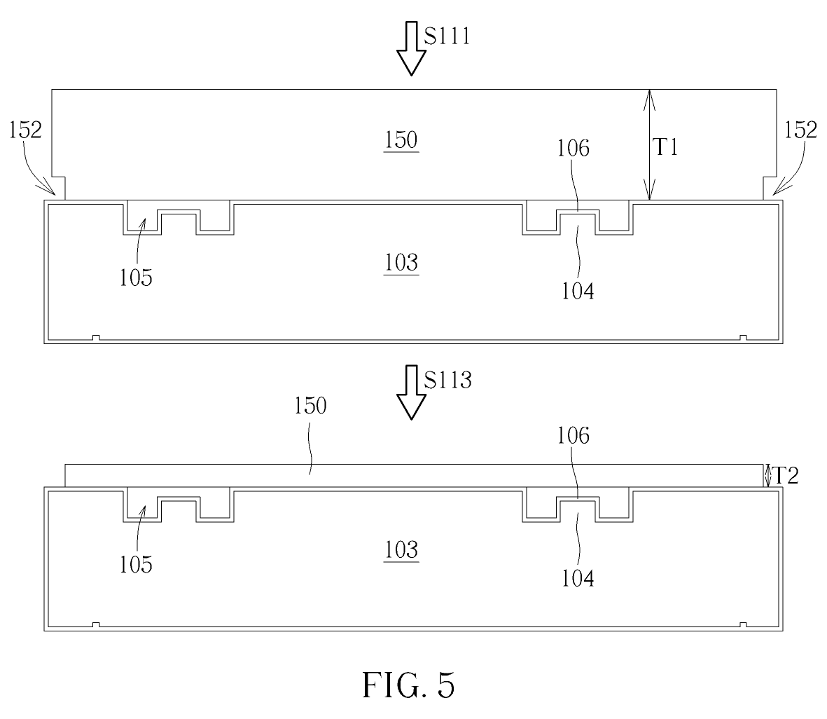

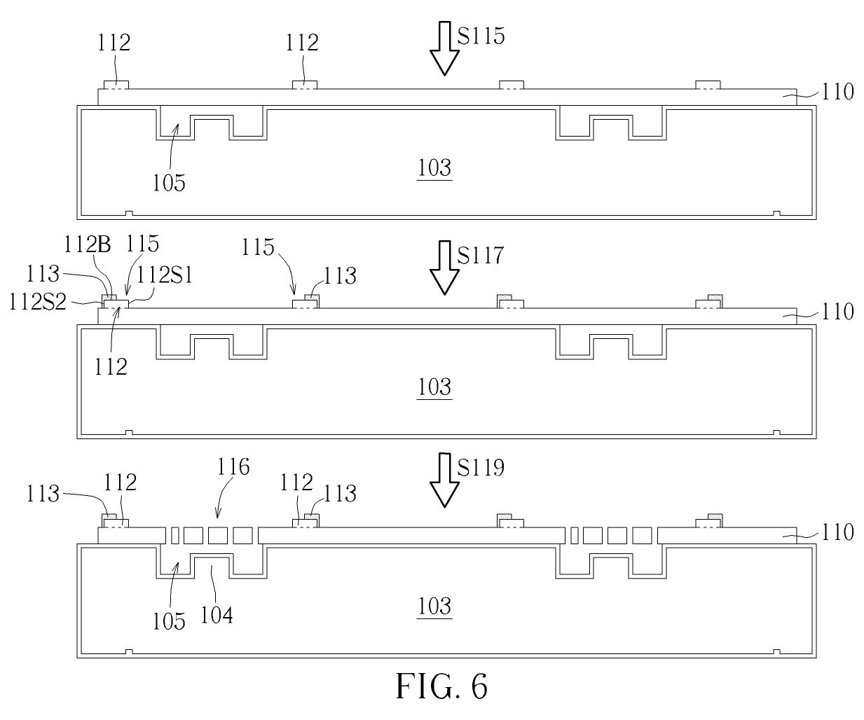

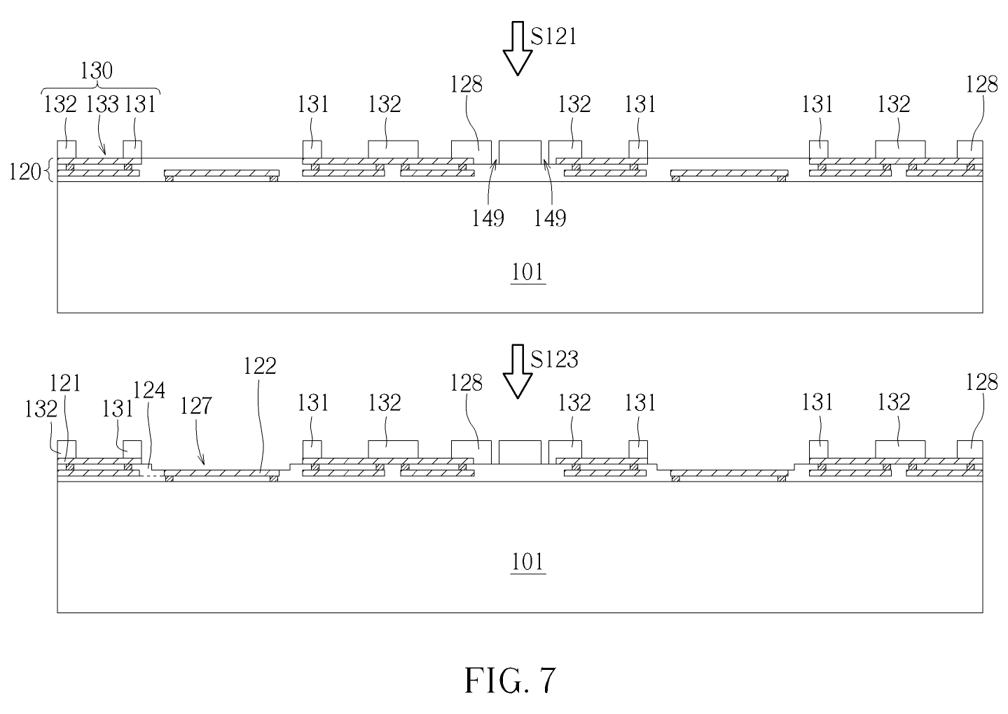

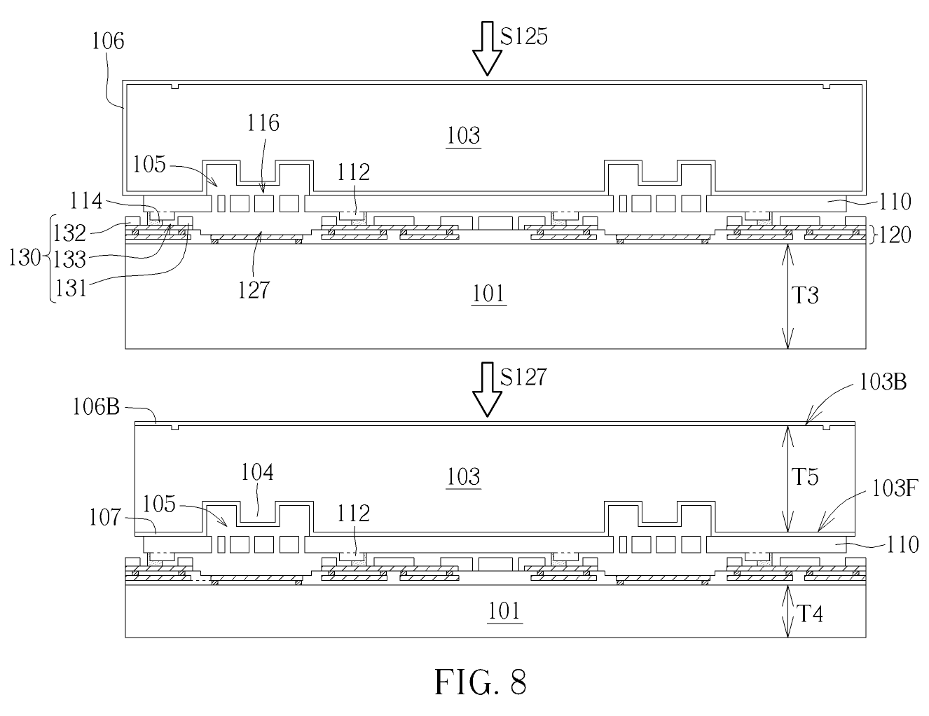

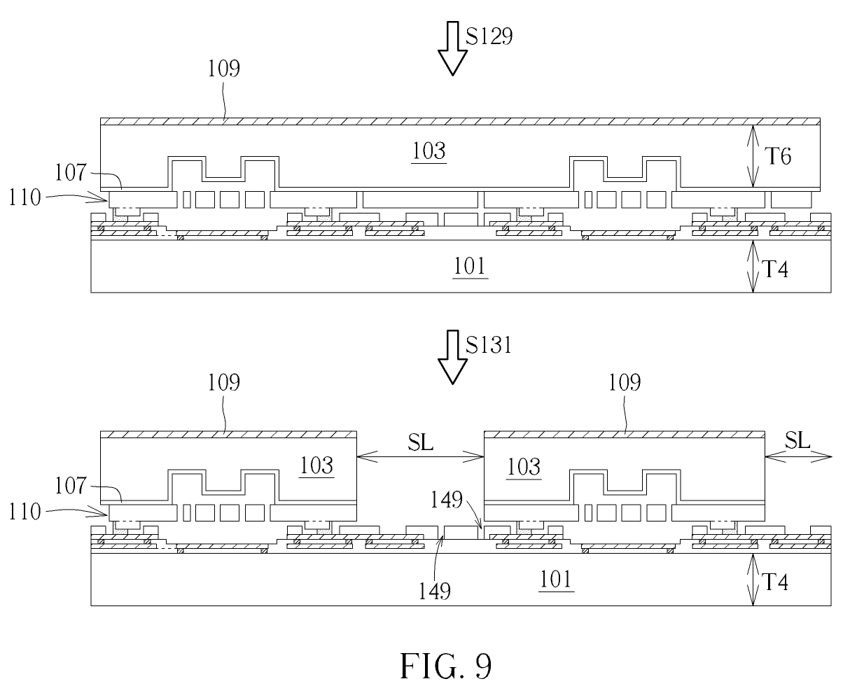

FIGS. 3, 4, 5, 6, 7, 8 and 9 are schematic cross-sectional views of some stages of a method of fabricating a MEMS package 100 according to one embodiment of the present disclosure. Referring to FIG. 3, in step S101, a second substrate 103 such as a silicon wafer is provided as a handle wafer or a cap wafer. The second substrate 103 is polished on both the front side and the back side. Multiple alignment marks 108 are formed on the back side of the second substrate 103 by patterning and etching. Next, a patterned hard mask 141 is formed on the front side of the second substrate 103 by deposition and patterning. The patterned hard mask 141 may be a silicon oxide layer.

Still referring to FIG. 3, in step S103, multiple shallow cavities 143 are formed on the front side of the second substrate 103 by etching and using the patterned hard mask 141 as an etching mask. The shallow cavities 143 have a depth P1, for example, about 2 µm. Thereafter, in step S105, a patterned photoresist mask 145 is formed on the bottom surfaces of the shallow cavities 143 by coating, exposure and development processes.

Next, referring to FIG. 4, in step S107, multiple stop bumps 104 and deep cavities 147 are formed in the second substrate 103 on its front side by etching and using both the patterned photoresist mask 145 and the patterned hard mask 141 as an etching mask. The stop bumps 104 have a height P2, for example, about 18 µm. The deep cavities 147 have a depth P3, for example, about 20 µm. The deep cavity 147 and the shallow cavity 143 constitute a cavity 105, and the stop bump 104 is formed in the cavity 105. The depth of the cavity 105 is greater than the height of the stop bump 104. The top surface of the stop bump 104 is lower than the front side of the second substrate 103. Thereafter, the patterned photoresist mask 145 and the patterned hard mask 141 are removed by stripping. Then, in step S109, a bonding layer 106 is conformally formed on the second substrate 103, in the cavities 105 and on the stop bumps 104 to wrap around the second substrate 103. The composition of the bonding layer 106 may be silicon oxide, and the bonding layer 106 may be formed by thermal oxidation.

Next, referring to FIG. 5, in step S111, a device wafer 150 such as a silicon wafer is provided and polished on its front side. The device wafer 150 may be heavily doped with boron to achieve a resistivity of about 0.008 ohm·cm to about 0.02 ohm·cm. Then, the device wafer 150 is trimmed at its edges 152 on the front side and bonded to the second substrate 103 by direct wafer bonding (oxide to silicon) through the bonding layer 106 without plasma treatment, covering the cavities 105 and the stop bumps 104. The device wafer 150 has a thickness T1 in step S111. Then, in step S113, the device wafer 150 is thinned by grinding on its back side to achieve a thickness T2 that is smaller than the thickness T1. In addition, a chemical-mechanical polish (CMP) process is performed on the back side of the thinned device wafer 150.

Next, referring to FIG. 6, in step S115, the thinned device wafer 150 is patterned by photolithography and etching processes to form stand-off structures 112 integrated with a MEMS device layer 110. The stand-off structures 112 protrude from a surface of the MEMS device layer 110. Then, in step S117, a bonding material 113 is formed on the outer sidewall 112S2 and a portion of the bottom surface 112B of the stand-off structure 112, but not on the inner sidewall 112S1 by deposition and patterning process. The bonding material 113 on the bottom surface 112B is indented from the inner sidewall 112S1 to generate a lateral recess 115 by the patterning process. The width of the lateral recess 115 may be less than 5 µm. In some embodiments, the bonding material 113 may be eutectic bonding material or thermo-compression bonding material. For example, the bonding material 113 may be germanium (Ge) for eutectic bonding, but is not limited thereto.

Afterwards, still referring to FIG. 6, in step S119, the MEMS device layer 110 is patterned by photolithography and etching processes to form MEMS devices 116 surrounded by the stand-off structures 112. The MEMS devices 116 are located directly above the cavities 105 and the stop bumps 104. In some embodiments, the MEMS devices 116 may be gyroscopes, accelerometers, an inertial measurement unit (IMU) device, and/or other MEMS device.

Next, referring to FIG. 7, in step S121, a first substrate 101 such as a CMOS wafer is provided with multiple CMOS transistors formed therein. Then, an interconnect layer 120 is formed on the front side of the first substrate 101. The details of the interconnect layer 120 may refer to the aforementioned descriptions of the MEMS device 100 in FIG. 1, and not repeated herein. Then, a dielectric stopper 130 and a passivation layer 128 are simultaneously formed on the interconnect layer 120 by deposition and patterning processes. The dielectric stopper 130 is formed on the seal ring of the interconnect layer 120. The seal ring is a portion of the top metal layer 121 and may be made of aluminum (Al). The dielectric stopper 130 includes a first portion 131, a second portion 132 and an opening 133. In addition, pre-cut lines 149 are formed in the passivation layer 128. The opening 133 of the dielectric stopper 130 and the pre-cut lines 149 in the passivation layer 128 may be simultaneously formed by the same etching process. The composition of the dielectric stopper 130 and the passivation layer 128 may be silicon oxide, silicon nitride or a combination thereof. Afterwards, in step S123, a top dielectric layer and the IMD layer 124 of the interconnect layer 120 are etched in sequence to form a stepped recess 127, thereby exposing a portion of the second-to-last metal layer 122. The first portion 131 of the dielectric stopper 130 is located around the stepped recess 127.

Next, referring to FIG. 8, in step S125, the structure in step S119 of FIG. 6 is inverted, and the MEMS device layer 110 is bonded to the interconnect layer 120 through the stand-off structure 112 and the bonding material 113. In one embodiment, the bonding material 113 may be Ge for eutectic bonding, and the seal ring of the interconnect layer 120 may be Al. After the MEMS device layer 110 is bonded to the interconnect layer 120 by eutectic bonding, a bonding material layer 114 of Al-Ge alloy is produced. The bonding material layer 114 is also indented a recessed distance from the inner sidewall of the stand-off structure 112. This prevents molten bonding material overflow when the MEMS device layer 110 is bonded to the interconnect layer 120. In addition, the stand-off structure 112 and the bonding material layer 114 are self-aligned within the opening 133 of the dielectric stopper 130. The first portion 131 and the second portion 132 of the dielectric stopper 130 are sufficiently thick to physically prevent the stand-off structure 112 from skidding during bonding of the MEMS device layer 110 to the interconnect layer 120, thereby limiting bond misalignment. In step S125, the first substrate 101 has a thickness T3.

Still referring to FIG. 8, in step 127, the first substrate 101 is thinned by grinding on its back side to achieve a thickness T4 that is smaller than the thickness T3. Then, the edges of the second substrate 103 are trimmed, thereby removing a portion of the bonding layer 106 on the side surfaces of the second substrate 103. Thereafter, a bonding layer 107 is formed on the front side 103F of the second substrate 103. A remaining bonding layer 106B is on the back side 103B of the second substrate 103. In step S127, the second substrate 103 has a thickness T5.

Next, referring to FIG. 9, in step S129, the second substrate 103 is thinned by grinding on its back surface to achieve a thickness T6 that is smaller than the thickness T5. Then, a metal layer 109 such as Al layer is deposited on the back surface of the second substrate 103. The thickness of the metal layer 109 is, for example about 0.8 µm. Then, in step S131, portions of the metal layer 109, the second substrate 103 and the MEMS device layer 110 at scribe lines SL are cut through by a tab dicing process with a saw blade, thereby exposing bond pads of the top metal layer 121 and the pre-cut lines 149. Thereafter, the interconnect layer 120 and the first substrate 101 are diced along the pre-cut lines 149 to complete the MEMS package 100 of FIG. 1.

According to embodiments of the present disclosure, the MEMS packages include the bonding material layer and the dielectric stopper to control and/or limit bond misalignment and bonding material overflow within the bonded device area. The formation of the bonding material layer and the dielectric stopper is integrated into the current fabrication of the MEMS package without adding any additional process steps. Therefore, the reliability and yield of the MEMS packages are improved while maintaining fabrication cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) package, comprising:
a first substrate;
an interconnect layer, disposed on the first substrate;
a MEMS device layer, including a MEMS device and disposed above the interconnect layer;
a stand-off structure, disposed under the MEMS device layer, around the MEMS device and bonded to the interconnect layer, wherein the stand-off structure comprise an inner sidewall, an outer sidewall and a bottom surface;
a bonding material layer, applied on the outer sidewall and a portion of the bottom surface of the stand-off structure; and
a second substrate, including a cavity and bonded to the MEMS device layer.

2. The MEMS package of claim 1, wherein the bonding material layer is not applied on the inner sidewall of the stand-off structure, and the bonding material layer on the portion of the bottom surface is indented a recessed distance from the inner sidewall.

3. The MEMS package of claim 2, wherein the recessed distance is less than 10% of a width of the stand-off structure.

4. The MEMS package of claim 1, further comprising a dielectric stopper, disposed on the interconnect layer and having an opening, wherein the stand-off structure and the bonding material layer are disposed in the opening of the dielectric stopper.

5. The MEMS package of claim 4, wherein a top surface of the dielectric stopper is higher than the bottom surface of the stand-off structure.

6. The MEMS package of claim 4, wherein the stand-off structure is a bond ring, the dielectric stopper comprises a first portion inside the stand-off structure and a second portion outside the stand-off structure, and the inner sidewall of the stand-off structure is spaced from the first portion by a first distance.

7. The MEMS package of claim 6, wherein the first distance is at least 5 µm.

8. The MEMS package of claim 6, wherein the bonding material layer on the outer sidewall of the stand-off structure is spaced from the second portion of the dielectric stopper by a second distance.

9. The MEMS package of claim 8, wherein the second distance is at least 5 µm.

10. The MEMS package of claim 4, wherein the dielectric stopper has a first thickness, the stand-off structure has a second thickness, and the first thickness is greater than a thickness of the bonding material layer on the stand-off structure and less than half of the second thickness.

11. The MEMS package of claim 4, wherein a bottom surface of the opening of the dielectric stopper and a bottom surface of the bonding material layer are on the same plane.

12. The MEMS package of claim 4, wherein a bottom surface of the dielectric stopper and a bottom surface of the bonding material layer are on the same plane.

13. The MEMS package of claim 1, wherein the bonding material layer comprises a eutectic bonding material or a thermo-compression bonding material.

14. The MEMS package of claim 13, wherein a composition of the bonding material layer comprises Al, Ge, Cu, Sn, Au, Al-Ge, Cu-Sn or Au-Sn.

15. The MEMS package of claim 1, further comprising a passivation layer disposed on the interconnect layer, wherein the dielectric stopper and the passivation layer have the same composition.

16. The MEMS package of claim 1, wherein a composition of the dielectric stopper comprises silicon oxide, silicon nitride or a combination thereof.

17. The MEMS package of claim 1, wherein the stand-off structure is integrated with the MEMS device layer and has the same composition as the MEMS device layer.

18. The MEMS package of claim 1, wherein the bonding material layer has a lateral recess directly below the stand-off structure and near the inner sidewall of the stand-off structure.

19. The MEMS package of claim 1, wherein the interconnect layer comprises:
a top metal layer, wherein the dielectric stopper and the bonding material layer are in direct contact with and disposed on a portion of the top metal layer;
a second-to-last metal layer, disposed below the top metal layer;
a dielectric layer, disposed between the top metal layer and the second-to-last metal layer; and
a stepped recess, disposed in both the top metal layer and the dielectric layer, exposing a portion of the second-to-last metal layer, and directly beneath the MEMS device.

20. The MEMS package of claim 19, wherein the dielectric stopper is adjacent to and surrounds the stepped recess.
